(19) United States
(12) Patent Application Publication
(10) Pub. No.: US 2014/0001588 A1
(43) Pub. Date: Jan. 2, 2014

(54) OPTICAL SENSORS DEVICES INCLUDING A HYBRID OF WAFER-LEVEL INORGANIC DIELECTRIC AND ORGANIC COLOR FILTERS

(71) Applicants: Michael I-Shan Sun, San Jose, CA (US); Francois Hebert, San Mateo, CA (US); Kenneth C. Dyer, Pleasanton, CA (US); Eric S. Lee, San Francisco, CA (US)

(72) Inventors: Michael I-Shan Sun, San Jose, CA (US); Francois Hebert, San Mateo, CA (US); Kenneth C. Dyer, Pleasanton, CA (US); Eric S. Lee, San Francisco, CA (US)

(73) Assignee: INTERSIL AMERICAS LLC, Milpitas, CA (US)

(21) Appl. No.: 13/535,925

(22) Filed: Jun. 28, 2012

(51) Int. Cl. H01L 27/14; H01L 31/18

(52) U.S. Cl. 257/432; 438/70; 438/68; 257/E31.121; 257/E27.122

(57) ABSTRACT

Monolithic optical sensor devices, and methods for fabricating such devices, are described herein. In an embodiment, a semiconductor wafer substrate includes a plurality of photodetector (PD) regions. A wafer-level inorganic dielectric optical filter is deposited and thereby formed over at least a subset of the plurality of PD regions. One or more wafer-level organic color filter(s) is/are deposited and thereby formed on one or more selected portion(s) of the wafer-level inorganic dielectric optical filter that is/are over selected ones of the PD regions. For example, an organic red filter, an organic green filter and an organic blue filter can be over, respectively, portions of the wafer-level inorganic dielectric optical filter that are over first, second and third PD regions.

### BACKGROUND

Photodetectors can be used as ambient light sensors (ALSs), e.g., for use as energy saving light sensors for displays, for controlling backlighting in portable devices such as mobile phones and laptop computers, and for various other types of light level measurement and management. For more specific examples, an ALS can be used to reduce overall display-system power consumption and to increase Liquid Crystal Display light source (LCD) lifespan by detecting bright and dim ambient light conditions as a means of controlling display and/or keypad backlighting. Without an ALS, LCD display backlighting control is typically done manually whereby a user will increase the intensity of the LCD as the ambient environment becomes brighter. With the use of an ALS, a user can adjust the LCD brightness to their preference, and as the ambient environment changes, the display brightness adjusts to make the display appear uniform at the same perceived level; this results in battery life being extended, user eye strain being reduced, and LCD lifespan being extended. Similarly, without an ALS, control of the keypad backlight is very much dependent on the user and software. For example, a keypad backlight can be turned on for 10 seconds by a trigger which can be triggered by pressing the keypad, or a timer. With the use of an ALS, keypad backlighting can be turned on only when the ambient environment is dim, which will result in longer battery life. In order to achieve better ambient light sensing, an ALS preferably has a spectral response close to the human eye response and has excellent infrared (IR) noise suppression (also referred to as IR rejection). Such a spectral response is often referred to as a “true human eye response” or a “photopic response”.

A potential problem with using a photodetector (such as a photodiode) as an ALS is that it detects both visible light and non-visible light, such as infrared (IR) light, which starts at about 700 nm. By contrast, the human eye does not detect IR light. Thus, the response of a photodetector can significantly differ from the response of a human eye, especially when the light is produced by an incandescent light, which includes large amounts of IR light. This would provide for significantly less than optimal adjustments if the photodetector were used as an ALS, e.g., for adjusting backlighting, or the like. Accordingly, various techniques have been attempted to provide light sensors (also referred to as optical sensors) that have a spectral response closer to that of the human eye, so that such light sensors can be used, e.g., for appropriately adjusting the backlighting of displays, or the like. Some of these techniques involve covering photodetectors with optical filters.

As can be appreciated from the above discussion, one potential desired response for a photodetector is a photopic response. However, this is just one exemplary response. For example, it may be desired that the response of one photodetector indicate how much red light is detected, the response of another photodetector indicate how much green light is detected, and the response of a further photodetector indicate how much blue light is detector. The responses of these three photodetectors can be combined, e.g., to provide a photopic response. Alternatively, the responses of these three photodetectors can be individually used as feedback to adjust colors in digital images captured using a digital camera and/or a digital video recorder, e.g., so that the captured images/videos more closely resemble what a person operating the camera/video recorder actually viewed. The responses of these three photodetectors can also be used for color adjustment for an LED back light system or an LED projector, for color detection and/or for white balance adjustment. Another potential desired response for a photodetector is detection of IR light and rejection of visible light, e.g., if the photodetector is being used in an IR based proximity and/or motion detector. Regardless of the exact response desired, it would be beneficial if photodetectors having any particular desired response can be fabricated in a manner that provides high accuracy and high yield.

Low cost semiconductor optical sensors are typically silicon photodiodes underneath mono-layer organic color filters. For example, conventional sensor designs often include dyed organic filters (also referred to as organic color filters) that are directly deposited on a passivation layer that covers a photodiode sensor region. The passivation layer is typically located on one or more inter-metal dielectric (IMD) layer(s) that also cover the photodiode sensor region. The dyed organic filters, which absorb specific light frequency ranges, have the advantage of low cost and ease of integration into conventional integrated circuit (IC) fabrication flows. A disadvantage of dyed organic filters is that they allow excessive infrared (IR) energy transmission. In other words, dyed organic filters are not good at absorbing wavelengths greater than 700 nm. However, where there is a desire to provide a photopic response, or to provide responses indicative of specific visible colors (e.g., red, green and/or blue), there is a need to filter out or otherwise reject wavelengths greater than 700 nm. Further, there is often a desire to include in the same package both an ALS and an IR-based proximity sensor. In such cases, there is a need to provide both a photodiode that rejects IR light, and a photodiode that detects IR light, within the same package.

### BRIEF DESCRIPTION OF THE DRAWINGS

FIG. 1A illustrates a monolithic optical sensor device according to an embodiment of the present invention.

FIG. 1B illustrates exemplary light transmissive specra for the red, green and blue organic filters.

FIG. 1C illustrates an exemplary light transmissive spectra for an inorganic dielectric optical filter configured as a short-wave pass filter, which can also be referred to as an IR-cut filter.

FIG. 2 illustrates a monolithic optical sensor device according to another embodiment of the present invention.

FIG. 3 illustrates a monolithic optical sensor device according to a further embodiment of the present invention.

FIG. 4 illustrates a monolithic optical sensor device according to still another embodiment of the present invention.

FIG. 5A-5E are used to illustrate how the monolithic optical sensor devices according to various embodiments of the present invention can be fabricated.

FIG. 6 illustrates a monolithic optical sensor device according to a specific embodiment of the present invention.

FIG. 7 illustrates a monolithic optical sensor device according to another specific embodiment of the present invention.

FIG. 8 illustrates a monolithic optical sensor device according to still another specific embodiment of the present invention

FIG. 9 is a high level flow diagram that is used to summarize methods for fabricating monolithic optical sensor devices according to certain embodiments of the present invention.

FIG. 10 illustrates a system, according to an embodiment of the present invention, which includes a monolithic optical sensor device.

### DETAILED DESCRIPTION

In the following detailed description, reference is made to the accompanying drawings that form a part hereof, and in which is shown by way of illustration specific illustrative embodiments. It is to be understood that other embodiments may be utilized and that mechanical and electrical changes may be made. The following detailed description is, therefore, not to be taken in a limiting sense. In the description that follows, like numerals or reference designators will be used to refer to like parts or elements throughout. In addition, the first digit of a reference number identifies the drawing in which the reference number first appears.

Certain embodiments of the present invention, which are described below, relate to monolithic optical sensor devices that include photodetectors (e.g., photodiodes), one or more wafer-level patterned inorganic dielectric optical filter(s), as well as one or more wafer-level patterned organic color filter(s). Certain embodiments of the present invention, which are described below, enable one or more photodetectors to reject IR light, while one or more further photodetectors detect IR light, even though all such photodetectors and filters are fabricated in/on a common semiconductor wafer substrate.

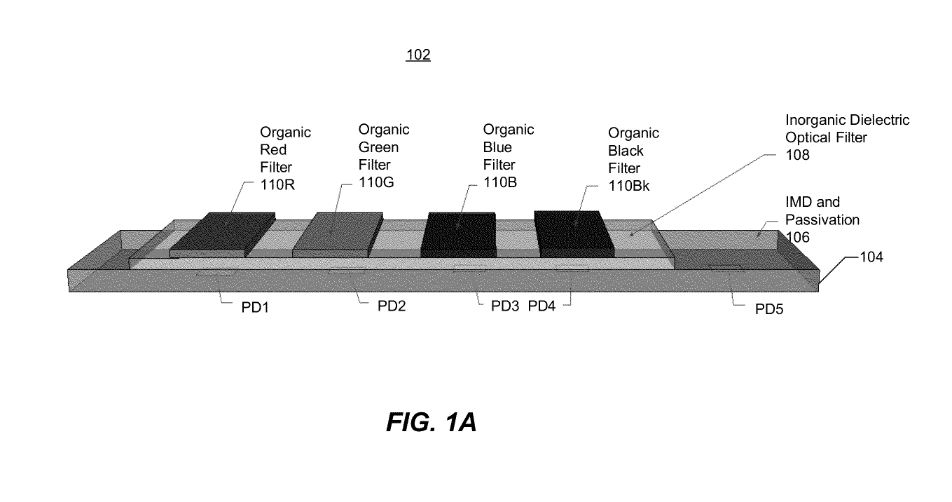

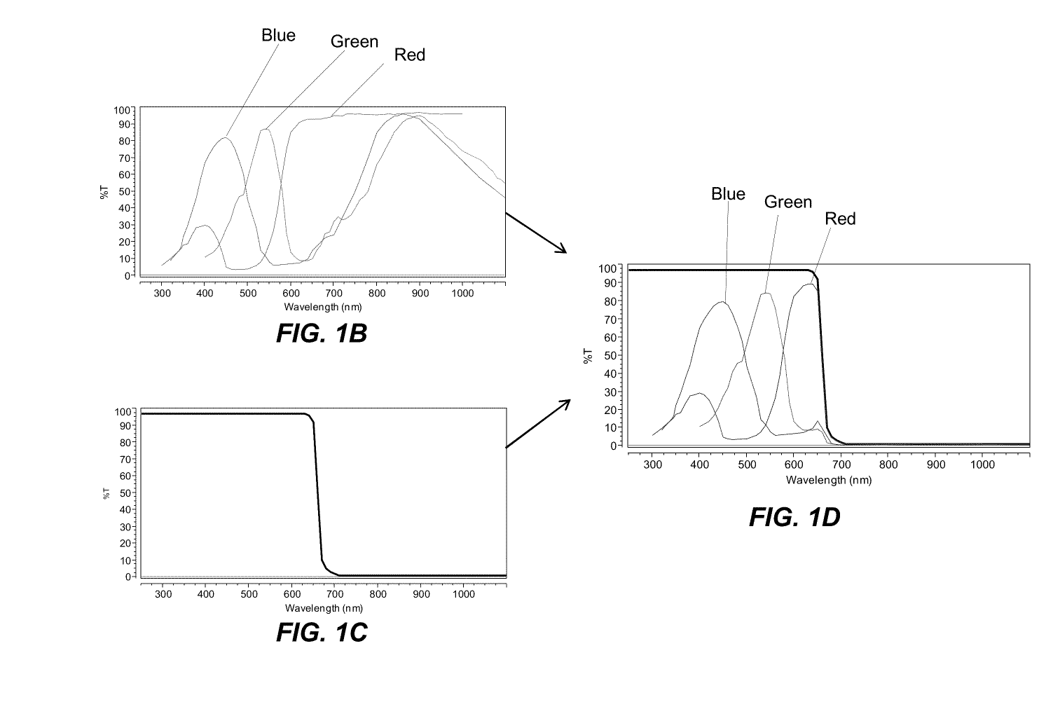

FIG. 1A shows a monolithic optical sensor device 102 according to an embodiment of the present invention. Referring to FIG. 1A, a semiconductor wafer substrate 104 is shown as including five photodetector (PD) regions, labeled PD1, PD2, PD3, PD4 and PD5. Each PD region can be, e.g., a photodiode, photoresistor, a photovoltaic cell, a phototransistor, or a charge-coupled device (CCD), but is not limited thereto, and can be used to produce a current or voltage indicative of detected light. For the remainder of this discussion, it will be assumed that each PD region is a photodiode, unless stated otherwise. It is also possible that each PD region is made up of an array of multiple photodiodes (or photoresistors, CCDs etc.) connected to one another (e.g., in series and/or parallel) so that they collectively produce a current or voltage indicative of detected light.

The entire surface of the wafer substrate 104 is covered by one or more inter-metal dielectric (IMD) layer(s), which can include one or more oxide and/or nitride, but is not limited thereto. One or more passivation layer(s) is/are likely above the uppermost IMD layer(s) 106. Passivation layers are typically categorized as either “hard” or “soft”. Hard passivation is typically silicon nitride while soft passivation is typically polyimide which is usually deposited over the hard passivation layer. Alternative passivation materials are also possible. The hard passivation layer(s) may or may not be planarized using CMP (chemical mechanical polishing). It is preferable for the passivation surface to be planar in optical sensor applications, but planar passivation is not a requirement for this invention. The IMD layer(s) and passivation layer(s) are collectively labeled 106.

A wafer-level inorganic dielectric optical filter 108 is patterned to cover PD1, PD2, PD3 and PD4, but not PD5. The patterned wafer-level inorganic dielectric optical filter 108 includes multiple layers of thin inorganic dielectric films. The individual thin film thicknesses typically range from about 10 nm to 300 nm, but are not limited thereto. The total thickness of the optical dielectric filter can range, e.g., from 2 μm to 10 μm, but is not limited thereto. Such inorganic dielectric films can be deposited using conventional semiconductor tooling to have, e.g., a high-low-high-low (HLHL) pattern of alternating refractive indices. Various conventional deposition methods can be employed to pattern the wafer-level inorganic dielectric optical filter 108, such as chemical vapor deposition (CVD), physical vapor deposition (PVD), plasma-enhanced CVD (PECVD), low-pressure CVD (LPCVD), metalorganic CVD (MOCVD), molecular beam epitaxy (MBE), epitaxy, evaporation, sputtering, atomic layer deposition (ALD), in-situ jet vapor deposition (JVD), and the like.

The dielectric materials used to form the wafer-level inorganic dielectric optical filter 108 can include silicon dioxide (SiO2), silicon hydride (SixHy), silicon nitride (SixNy), silicon oxynitride (SixOzNy), tantalum oxide (TaxOy), gallium arsenide (GaAs), gallium nitride (GaN), and the like. Alternating layers in the optical filter may have a constant or varying film thickness throughout the filter stack, in order to achieve the desired optical response. By careful choice of the exact composition, thickness, and number of these layers, it is possible to tailor the reflectivity and transmissivity of the optical filter to produce almost any desired spectral characteristics. For example, the reflectivity can be increased to greater than 99.99%, to produce a high-reflector (HR) coating. The level of reflectivity can also be tuned to any particular value, for instance to produce a mirror that reflects 90% and transmits 10% of the light that falls on it, over some range of wavelengths. Such mirrors have often been used as beam splitters, and as output couplers in lasers. Alternatively, the wafer-level inorganic dielectric optical filter 108 can be designed such that the mirror reflects light only in a narrow band of wavelengths, producing a reflective optical filter.

Generally, layers of high and low refractive index materials are alternated one above the other. This periodic or alternating structure significantly enhances the reflectivity of the surface in the certain wavelength range called band-stop, which width is determined by the ratio of the two used indices only (for quarter-wave system), while the maximum reflectivity is increasing nearly up to 100% with a number of layers in the stack. The thicknesses of the layers are generally quarter-wave (then they yield to the broadest high reflection band in comparison to the non-quarter-wave systems composed from the same materials), designed such that reflected beams constructively interfere with one another to maximize reflection and minimize transmission. Using the above described structures, high reflective coatings can achieve very high (e.g., 99.9%) reflectivity over a broad wavelength range (tens of nanometers in the visible spectrum range), with a lower reflectivity over other wavelength ranges, to thereby achieve a desired spectral response. By manipulating the exact thickness and composition of the layers in the reflective stack, the reflection characteristics can be tuned to a desired spectral response, and may incorporate both high-reflective and anti-reflective wavelength regions. The wafer-level inorganic dielectric optical filter 108 can be designed as a long-pass or short-pass filter, a bandpass or notch filter, or a mirror with a specific reflectivity. In specific embodiments of the present invention, the wafer-level inorganic dielectric optical filter 108 is designed as a short-pass filter that passes visible wavelengths less than 700 nm, and rejects wavelengths (e.g., including IR wavelengths) above 700 nm, in which case the wafer-level inorganic dielectric optical filter 108 can be referred to as an IR-cut filter.

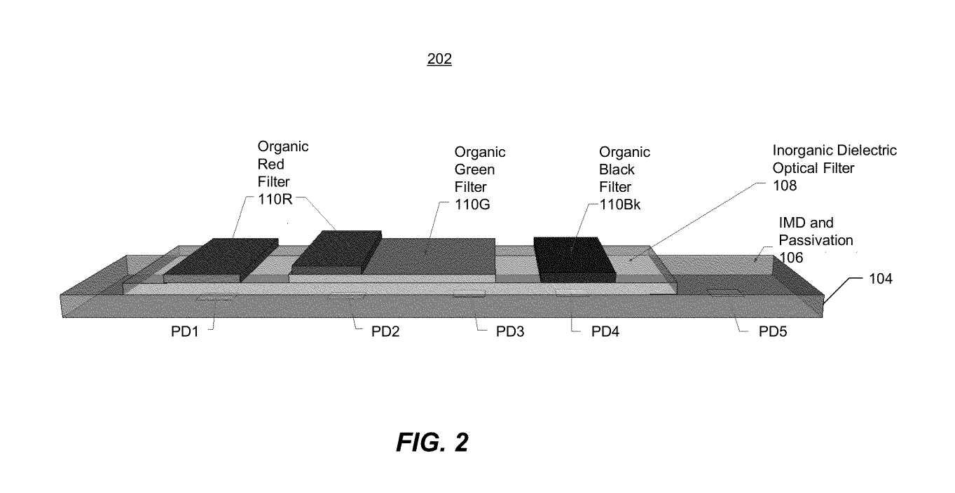

Still referring to FIG. 1A, each of PD1, PD2, PD3 and PD4 is shown as also be covered by a different wafer-level patterned organic color filter 110. Such patterned organic color filters can be similar in composition to a photoresist, and can have a thickness, e.g., of 0.5 to 2 μm. These organic color filters are typically spun-on photoactive organic films with pigment additives to result in absorption of desired light frequencies (e.g., blue, green, or red). In FIG. 1A, PD1 is covered by both the wafer-level inorganic dielectric optical filter 108 and a wafer-level organic red filter 110R. PD2 is covered by both the wafer-level inorganic dielectric optical filter 108 and a wafer-level organic green filter 110G. PD3 is covered by both the wafer-level inorganic dielectric optical filter 108 and a wafer-level organic blue filter 110B. PD4 is covered by both the wafer-level inorganic dielectric optical filter 108 and a wafer-level organic black filter 110Bk. PD5 is not covered by the wafer-level inorganic dielectric optical filter 108 and is not covered by any organic color filter 110. In FIG. 1A, and FIGS. 2-8, the various layers are not drawn to scale. For example, it is possible that the IMD layer(s) and passivation layer(s) 106 collectively are thicker than the wafer-level inorganic dielectric optical filter 108 and/or the organic color filters 110.

It is noted that a wafer-level inorganic dielectric optical filter, such as the filter 108, is typically relatively expensive to implement, because the deposition process (e.g., sputtering or evaporation) of alternating dielectric material at very fine geometries (tenth to hundreds of nanometer), with precision control to the layer thickness and material composition, typically takes several hours. Additionally, a wafer-level inorganic dielectric optical filter is typically patterned using a photoresist lift-off in a chemical solvent bath, which is typically costly due to the relatively long residence time (i.e., soak duration) in the photoresist solvent bath, and due to a relatively narrow process margin. Thus, if there is a desire to achieve multiple (e.g., three or more) different photodetector responses using a single monolithic optical sensor device, it would be quite costly to achieve the multiple different responses using multiple separate wafer-level inorganic dielectric optical filters to achieve the multiple responses. This is because it would require multiple deposition and multiple lift-off processes to form multiple different wafer-level inorganic dielectric optical filters on a common semiconductor substrate, which would require a very long cycle time. Specific embodiments of the present invention, described herein, take advantage of the common denominator of the multiple desired response, e.g., IR rejection, in order utilize a common wafer-level inorganic dielectric optical filter in combination with multiple organic color filters for achieving multiple different photodetector responses using a single monolithic optical sensor device.

FIG. 1B illustrates an exemplary light transmissive specra for the red, green and blue organic filters. FIG. 1C illustrates an exemplary light transmissive specra for a dielectric optical filter designed as a short-wave pass filter, which can also be referred to as an IR-cut filter since it cuts or rejects IR light. FIG. 1D illustrates the light transmission spectra that can be achieved by patterning the various organic color filters above the inorganic dielectric optical filter. Advantageously, the inorganic dielectric optical filter can be used to reject, and more specifically reflect, wavelengths above 700 nm. This enables the PD regions covered by the red, green and blue organic filters (as well as the dielectric optical filter) to primarily detect red, green and blue light, respectively.

FIG. 2 shows a monolithic optical sensor device 202 according to another embodiment of the present invention. In FIG. 2, a semiconductor wafer substrate 104 is again shown as including five PD regions labeled PD1, PD2, PD3, PD4 and PD5. The entire surface of the wafer substrate again covered by one or more IMD layer(s) and passivation layer(s), collectively labeled 106. A wafer-level inorganic dielectric optical filter 108 is again patterned to cover PD1, PD2, PD3 and PD4, but not PD5. PD1 is covered by both the wafer-level inorganic dielectric optical filter 108 and a wafer-level organic red filter 110R. PD2 is covered by both the wafer-level inorganic dielectric optical filter 108, a wafer-level organic green filter 110G and a wafer-level organic red filter 110R. In other words, the organic green and the organic red filters are stacked one above the other, with that stack being above the inorganic dielectric optical filter 108. PD3 is covered by both the inorganic dielectric optical filter 108 and the organic green filter 110G. PD4 is covered by both the inorganic dielectric optical filter 108 and an organic black filter 110Bk. PD5 is covered by neither the inorganic dielectric optical filter 108 nor any organic color filter 110.

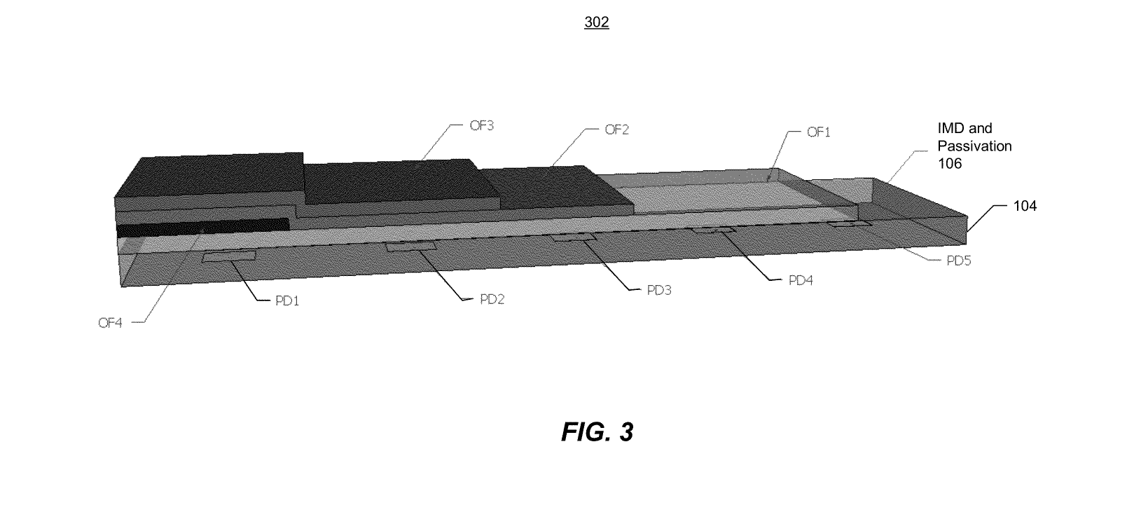

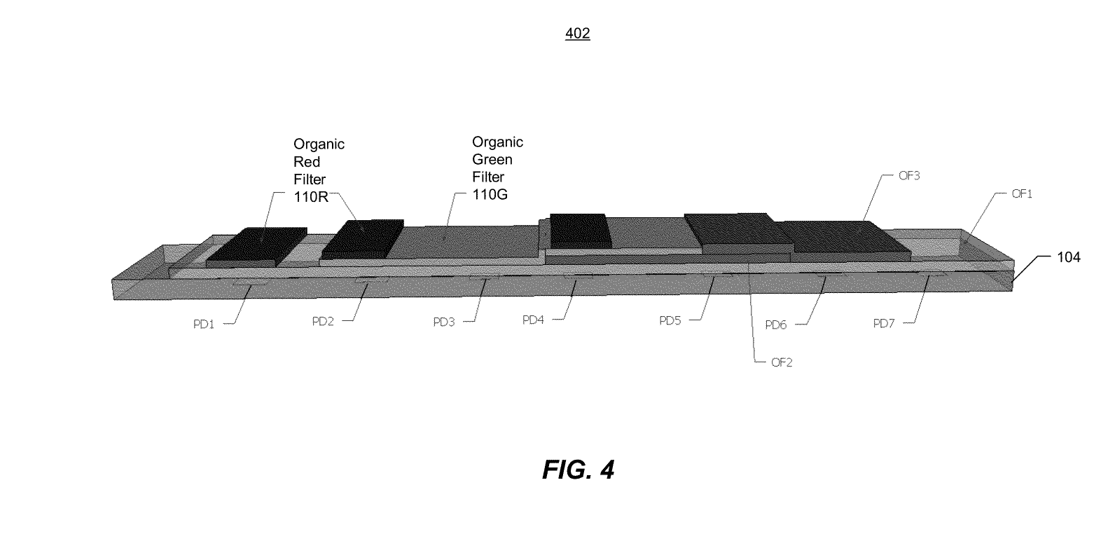

FIG. 3 illustrates a monolithic optical sensor device 302 where various wafer-level inorganic dielectric optical filters, labeled OF1, OF2, OF3 and OF4, are stacked in different combinations. While not shown in FIG. 3, one or more organic color filters can also be added to the stack of dielectric filters. An example of this is shown in FIG. 4, which illustrates a monolithic optical sensor device 402 which is a combination of the embodiments of FIGS. 2 and 3. Compared to the other embodiments described herein, the embodiments of FIGS. 3 and 4 would likely be more costly because they require the multiple deposition and lift-off processes to provide the multiple wafer-level inorganic dielectric optical filters (e.g., OF1, OF2, OF3 and OF4). FIG. 4 also includes additional PD regions PD6 and PD7.

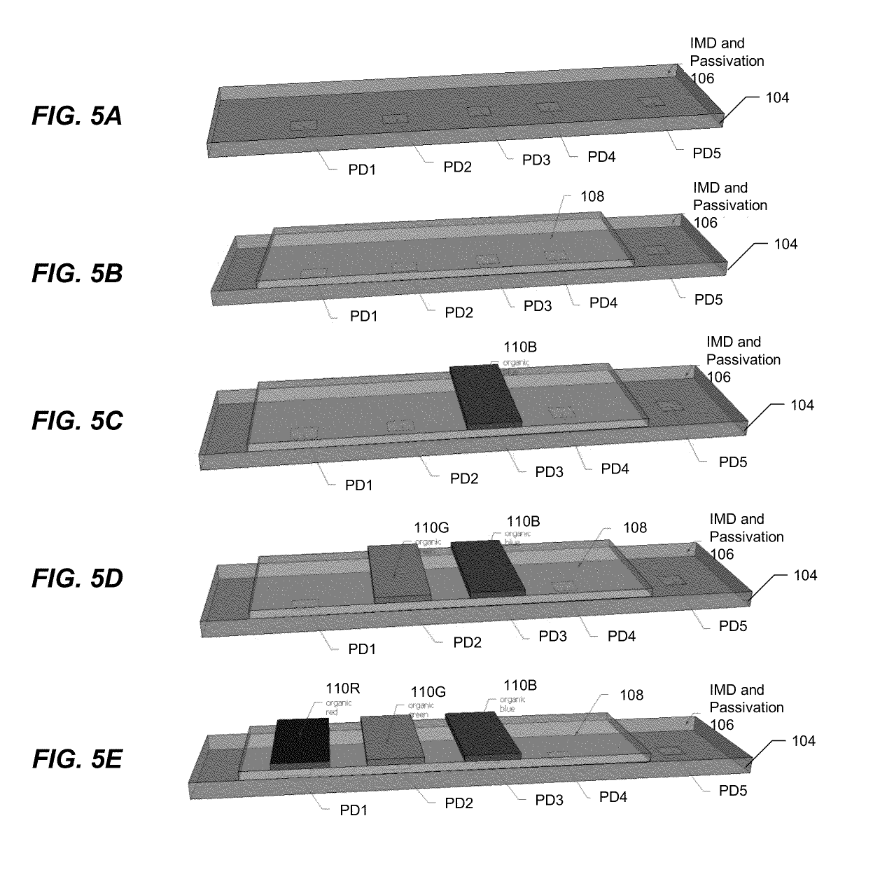

FIGS. 5A-5E illustrates an exemplary process flow for fabricating the monolithic optical sensors described above. Referring first to FIG. 5A, five PD regions labeled PD1, PD2, PD3, PD4 and PD5 are formed in a semiconductor wafer using any well known technique, and the surface of the wafer and the PDs are covered with one or more IMD layer(s) and a passivation layer. The wafer will likely include thousands of such PD regions, thereby enabling hundreds of monolithic optical sensor devices to be fabricated on a same wafer. Toward the end of the fabrications process the wafer is diced into individual monolithic optical sensor devices, which each include, in this example, five PD regions.

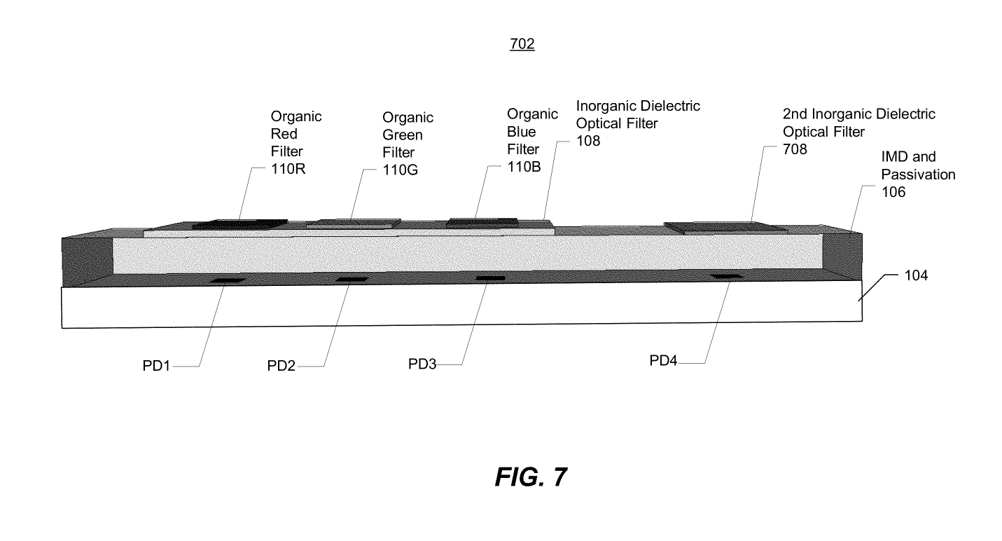

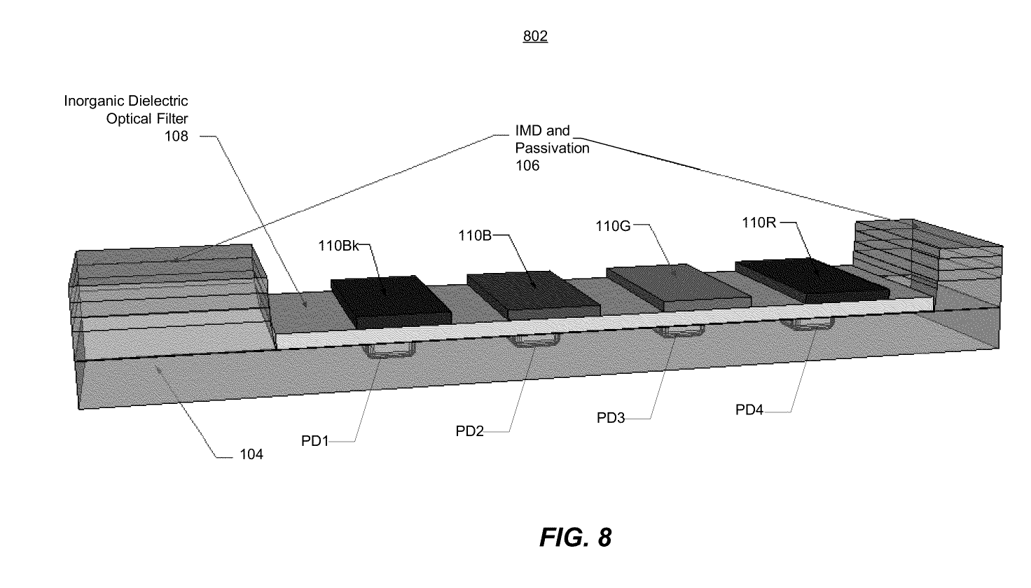

Referring now to FIG. 5B, one or more of the PD regions (in this example, PD1, PD2, PD3 and PD4) are covered by a wafer-level inorganic dielectric optical filter 108. This can be achieved by covering the entire surface of the wafer semiconductor substrate 104 (and more specifically the uppermost IMD or passivation layer) with a photoresist, using photolithography to define a pattern in the photoresist, and then using a developer to remove a portion of the photoresist covering the PD regions that are to be covered by the inorganic dielectric optical filter 108. Next, inorganic dielectric optical filter layers are deposited over both the areas where the photoresists had been removed as well as where the areas where the photoresist remained. As mentioned above, various conventional deposition methods can be employed in depositing the inorganic optical dielectric filter layers (used for form the filter 108), such as CVD, PECVD, LPCVD, MOCVD, MBE, epitaxy, evaporation, sputtering, PVD, ALD, in-situ JVD, and the like. A lift-off is then performed using a chemical solvent to remove the portion of the dielectric optical filter layers that are over the remaining photoresist and to leave the dielectric optical filter layers that are over specific PD regions (where the photoresist had previously been removed). Where there is a desired to form more than one different wafer-level inorganic dielectric optical filter (e.g., as in the embodiments described above with reference to FIGS. 3 and 4, and as in the embodiment described below with reference to FIG. 7), the aforementioned deposition and lift-off processes can be repeated to form one or more additional wafer-level inorganic dielectric optical filter.

Referring now to FIG. 5C, one of the PD regions (PD3) is covered by a blue organic filter 110B. Thereafter, another one of the PD regions (PD2) is covered by a green organic filter 110G, as shown in FIG. 5D. A red organic filter 110R is then added to cover a further one of the PD regions (PD1), as shown in FIG. 5E.

Where each of the organic color filters 110 is essentially a dyed photoresist material, each organic color filter layer can be patterned using photolithography in the same manners that photoresist is conventionally patterned. There exist both positive and negative types of photoresists, and depending on the exact materials used, the organic color filters 110 can either behave as a positive type of photoresist, or a negative type of photoresist. When a positive photoresist is exposed to UV light the chemical structure of the photoresist changes so that it becomes more soluble in a developer. The exposed photoresist is then washed away by the developer, leaving windows in the photoresist where the photoresist was exposed to UV light. Accordingly, when using a positive photoresist the photomask includes an exact copy of the pattern which is to remain on the wafer. Negative photoresists behave in the opposite manner. That is, exposure to the UV light causes the negative photoresist to become less soluble in a developer. Therefore, the negative photoresist remains on the surface wherever it was exposed, and the developer removes only the unexposed portions. Accordingly, a photomask used with a negative photoresist includes the inverse (or photographic “negative”) of the pattern to be transferred.

As mentioned above, hundreds of such monolithic optical sensor devices are likely being fabricated on a same wafer. Accordingly, after the various organic color filters 110 are patterned, as explained with reference to FIGS. 5C, 5D and 5E, the wafer is diced into individual monolithic optical sensor devices, which each include, in this example, five PD regions. However, it is also within the scope of the present invention for each monolithic optical sensor device to include other numbers of PD regions.

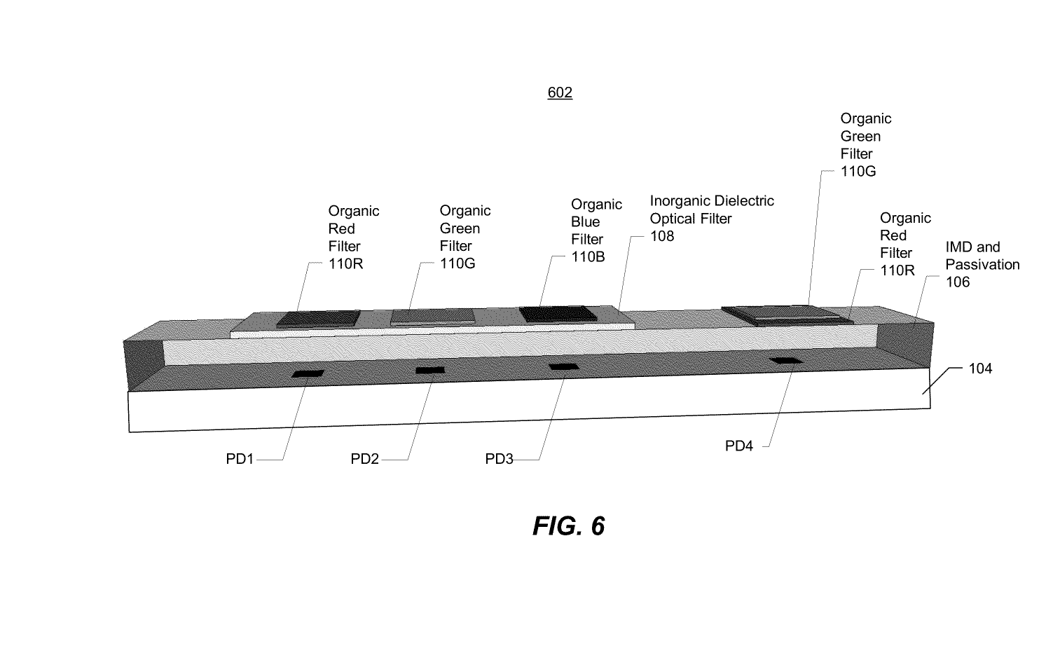

FIG. 6 shows a monolithic optical sensor device 602 according to an embodiment of the present invention. In FIG. 6, a semiconductor wafer substrate 104 is shown as including four PD regions labeled PD1, PD2, PD3 and PD4. The entire surface of the wafer substrate again covered by one or more IMD layer(s) and passivation layer(s), collectively labeled 106. A wafer-level inorganic dielectric optical filter 108 is patterned to cover PD1, PD2 and PD3, but not PD4. PD1 is covered by both the wafer-level inorganic dielectric optical filter 108 and a wafer-level organic red filter 110R. PD2 is covered by both the wafer-level inorganic dielectric optical filter 108 and a wafer-level organic green filter 110G. PD3 is covered by both the wafer-level inorganic dielectric optical filter 108 and a wafer-level organic red filter 110R. Accordingly, PD1, PD2 and PD3 and their filters respectively detect red (R), green (G) and blue (B) light, and thus, can be referred to as RGB detectors. PD4 is covered by both a wafer-level organic red filter 110R and a wafer-level organic green filter 110G, and can be useful as an IR-based proximity and/or motion detector that detects IR light (transmitted by a light source, not shown) that has reflected off of an object within the sense region of the PD4.

In FIG. 6, the desire is for PD1, PD2 and PD3 to detect specific visible colors of light, and to reject IR light. This embodiment, as well as many other embodiments described herein, take advantage of the common denominator of the multiple desired responses, IR rejection in this case, in order utilize a common wafer-level inorganic dielectric optical filter 108 for achieving multiple different photodetector responses using a single monolithic optical sensor device. In other words, in FIG. 6 to wafer-level inorganic dielectric optical filter 108 is an IR-cut filter.

FIG. 7 illustrates a monolithic optical sensor device 702 according to another specific embodiment of the present invention. In FIG. 7, a semiconductor wafer substrate 104 is shown as including four PD regions labeled PD1, PD2, PD3 and PD4. The entire surface of the wafer substrate again covered by one or more IMD layer(s) and passivation layer(s), collectively labeled 106. A wafer-level inorganic dielectric optical filter 108 is patterned to cover PD1, PD2 and PD3, but not PD4. PD1 is covered by both the wafer-level inorganic dielectric optical filter 108 and a wafer-level organic red filter 110R. PD2 is covered by both the wafer-level inorganic dielectric optical filter 108 and a wafer-level organic green filter 110G. PD3 is covered by both the wafer-level inorganic dielectric optical filter 108 and a wafer-level organic red filter 110R. As in the embodiment of FIG. 6, PD1, PD2 and PD3 and their filters respectively detect red (R), green (G) and blue (B) light, and thus, can be referred to as RGB detectors. Here, PD4 is covered by a second wafer-level inorganic dielectric optical filter 108 that is patterned to only cover PD4, but not the other PD regions. In an embodiment, the second wafer-level inorganic dielectric optical filter 108 is designed as a long-pass filter, so that PD4 can be useful as an IR-based proximity and/or motion detector that detects IR light (transmitted by a light source, not shown) that has reflected off of an object within the sense region of the PD4. By contrast, that wafer-level inorganic dielectric optical filter 108 that covers PD1, PD2 and PD3 is an IR-cut filter.

In FIGS. 6 and 7, the signals (e.g., photocurrents) produce by PD1, PD2 and PD3 can be combined (e.g., using a weighted summation) to produce a signal having a photopic response, which can be used as an ALS. It is also within the scope of an embodiments of the present invention to use PD2 (which is covered by the wafer-level inorganic dielectric optical filter 108 and the wafer-level organic green filter 110G) as an ALS, since the response of a PD covered by an IR-cut filter and a green filter is generally similar to a photopic response.

FIG. 8 illustrates a monolithic optical sensor device 802 where the inorganic dielectric optical filter 108 and organic color filters 110 are formed directly above the PD regions after a trench is formed to remove most or all of the IMD layer(s) that cover the PD regions. In certain embodiments, the only thing between the PD regions and the dielectric optical filter is a thin layer, such an anti-reflective layer (ARC), such as Si₃N₄, or a contact etch stop layer (CESL). Here, the IMD layer(s) has/have been removed by patterned etch step(s) prior to filter deposition. Commonly assigned U.S. patent application Ser. No. 13/466,867, filed May 8, 2012, and entitled OPTICAL SENSOR DEVICES INCLUDING FRONT-END-OF-LINE (FEOL) OPTICAL FILTERS AND METHODS FOR FABRICATING OPTICAL SENSOR DEVICES, provides additional details of how a trench can be formed, PD regions can be formed under the trench, and a dielectric optical filter can be formed in the trench and over the PD regions.

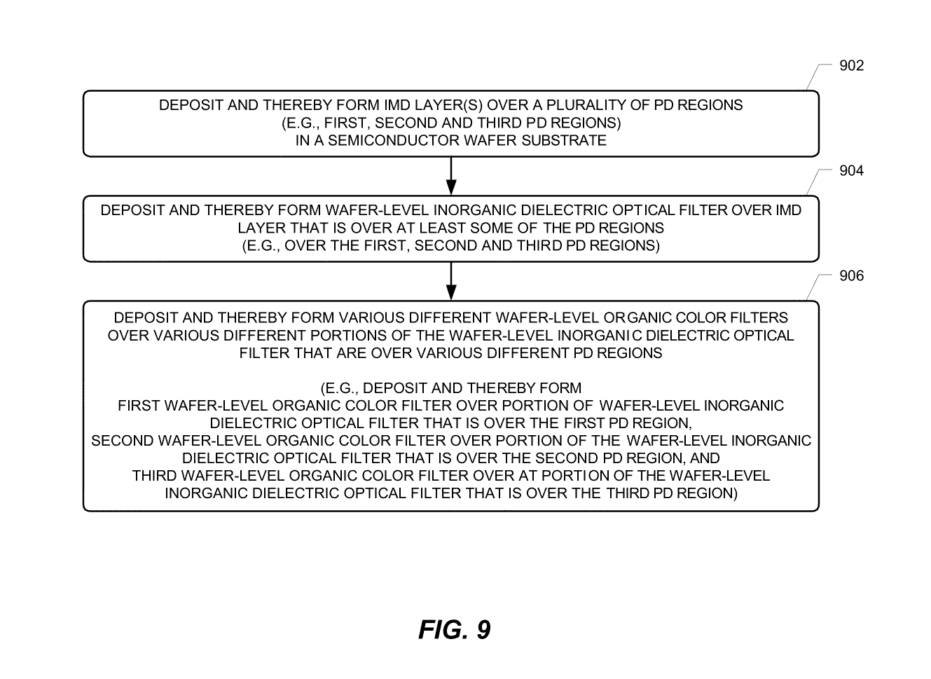

The high level flow diagram of FIG. 9 will now be used to summarize methods for manufacturing monolithic optical sensor devices, according to certain embodiments of the present invention. Referring to FIG. 9, at step 902, one or more IMD layer(s) are deposited and thereby formed over a plurality of PD regions (e.g., a first PD region, a second PD region and a third PD region) in a semiconductor wafer substrate. At step 904, a wafer-level inorganic dielectric optical filter is deposited and thereby formed over at least a portion of an uppermost IMD layer that is over at least some of the PD regions (e.g., over the first, second and third PD regions). As mentioned above, this will require both deposition and lift-off processes. At step 906, various different wafer-level organic color filters are deposited and thereby formed above various different PD regions. In a specific embodiment, a first wafer-level organic color (e.g., red) filter is formed over at least a portion of the wafer-level inorganic dielectric optical filter that is over the first PD region; a second wafer-level organic color (e.g., green) filter is formed over at least a portion of the wafer-level inorganic dielectric optical filter that is over the second PD region; and a third wafer-level organic color (e.g., blue) filter is formed filter over at least a portion of the wafer-level inorganic dielectric optical filter that is over the third PD region. In specific embodiments, the wafer-level inorganic dielectric optical filter is an IR-cut filter configured to reject IR light and pass visible light. As was explained above, between step 902 and 904, a passivation layer can be deposited and thereby formed above an uppermost IMD layer.

More or less than three PD regions can be included. For example, there can also be a fourth PD region in the substrate that is intended to be used to detect IR light for IR based proximity and/or motion detection. As was described above with reference to FIG. 6, such a fourth PD region can be covered by one or more wafer-level organic color filter(s) to attempt to reject visible light and pass IR light. As was described above with reference to FIG. 7, such a fourth PD region can alternatively be covered by a further wafer-level inorganic dielectric optical filter configured to pass infrared IR light and reject visible light. Other variations are possible, as can be appreciated from the above discussion of FIGS. 1-8. For example, as was described with reference to FIG. 8, the PD regions can be formed in a trench, and the various filters can be formed in the trench directly above the PD regions, rather than above the IMD layer(s). Additional details of how to form the various filters have been provided above, and thus, are not repeated here.

The wafer-level inorganic dielectric optical filters (e.g., 108, 708, OF1, OF2, OF3 and OF4) and the wafer-level organic color filters (e.g., 110R, 110G, 110B and 110Bk) described herein are considered “wafer-level” filters because they are formed on a wafer prior to dicing the wafer into a plurality of dies (where each die is, or includes, one of the monolithic optical sensor devices described herein). In certain embodiments of the present invention, a wafer, prior to dicing, can include a semiconductor substrate (e.g., 104), PDs formed in the substrate, IMD and passivation layer(s) (e.g., 106) formed above the substrate, as well as the inorganic dielectric optical filters (e.g., 108, 708, OF1, OF2, OF3 and OF4) and the organic color filters (e.g., 110R, 110G, 110B and 110Bk) formed above the IMD and passivation layer(s). A waver can include alternative configurations, e.g., one example of which was described above with reference to FIG. 8.

Monolithic optical sensor devices of embodiments of the present invention can be used in various systems, including, but not limited to, mobile phones, cameras, video recorders, projectors, tablets, personal data assistants, laptop computers, netbooks, other handheld-devices, as well as non-handheld-devices. Such sensor devices can be used to achieve various different responses, which depend on the specific applications in which the sensor devices are to be used. For example, a monolithic optical sensor device according to an embodiment of the present invention can include a PD that indicates how much red light is detected, another PD that indicates how much green light is detected, and another PD that indicates how much blue light is detector. The responses of these three PDs can be combined, e.g., to provide a photopic response. Alternatively, the responses of these three PDs can be individually used as feedback to adjust colors in digital images captured using a digital camera and/or a digital video recorder, e.g., so that the captured images/videos more closely resemble what a person operating the camera/video recorder actually viewed. The responses of these three PDs can also be used for color adjustments for a television, an LED back light system or an LED projector, or for color detection and/or for white balance adjustment. The responses of these three PDs can be combined for use as an ALS, or the response of one of the PDs can be used alone as an ALS. The responses of these three PDs can also be used to decrease shutter speeds in a digital camera. For example, a CPU of a digital camera can use the responses of the three PDs to perform temperature calculations, instead of requiring that the CPU perform the color temperature calculations based on signals from a pixel array behind a camera lens.

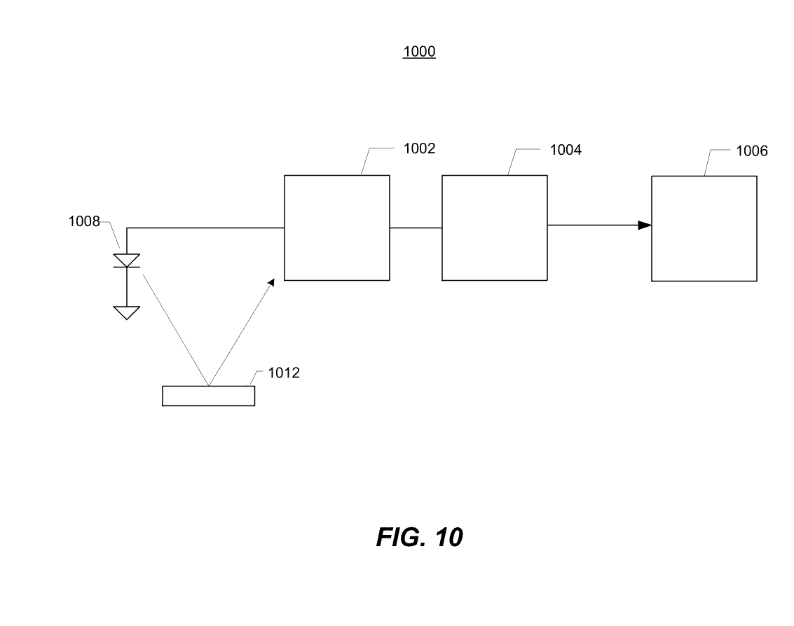

Referring to the system 1000 of FIG. 10, for example, a monolithic optical sensor device 1002 (e.g., 602 or 702) can be used to control whether a subsystem 1006 (e.g., a touch-screen, display, backlight, virtual scroll wheel, virtual keypad, navigation pad, etc.) is enabled or disabled, as well as to control a feature (e.g., the brightness) of the subsystem 1006 (or another subsystem). More specifically, one or more PD region(s) of the monolithic optical sensor device 1002 can be covered by one or more filters to function as an ALS, while one or more other PD region(s) of the monolithic optical sensor device 1002 can be covered by one or more filters to function as an IR-based (or other wavelength based) proximity sensor. The monolithic optical sensor device 1002 (or some other circuit) can include a driver that selectively drives a light source 1008 (e.g., an IR light emitting diode), and one or more PD region(s), which are covered by filter(s) tuned the wavelengths produced by the light source 1008, can be used to detect the presence, proximity and/or motion of an object 1012 with the sense region of such PD region(s). Outputs of the sensor device 1002 can be provided to one or more comparators and/or a processor 1004 which can, e.g., compare the outputs of the sensor device 1002 to thresholds, to determine whether the object 1012 is within a range where the subsystem 1006 should be enabled (or disabled, depending on what is desired). Multiple thresholds (e.g., stored digital values) can be used, and more than one possible response can occur based on the detected proximity of an object. For example, a first response can occur if an object is within a first proximity range, and a second response can occur if the object is within a second proximity range. Exemplary responses can include starting or stopping, or enabling or disabling, various system and/or subsystem operations. An output of the sensor device 1002 can also be used to adjust a feature (e.g., brightness) of the subsystem 1006, or some other subsystem.

In accordance with an embodiment, one or more PD regions can be covered by a light blocking material (e.g., a metal layer) that does not let any light through. The PD region(s) that are covered by the light blocking material will produce a current, known as a dark current or a leakage current, that varies with changes in temperature and variations in processing conditions. Similarly, a small portion of the current generated by the other PD region(s) (not covered by a light blocking material) will be due to a dark current, while the remaining portion of the current is primarily indicative of detected light (the wavelengths of which are dependent upon the filter(s) above the PD region(s)). By covered a PD region by the light blocking material, the dark current generated by PD region covered by the light blocking material can be subtracted from a current(s) generated by the other PD region(s), to remove the affects of the dark current.

Alternatively, or additionally, one or more of the PD region(s), which is not covered by any filter, and thus can be referred to as a naked PD region, can be used detect both ambient visible light and ambient IR light. Assume other PD region(s) are covered by one or more filters designed to filter out ambient visible light while passing ambient IR light, and thus, produce a current indicative of ambient IR light. By subtracting the current indicative of ambient IR light from the current generated by the naked optical sensor device(s), a current indicative of ambient visible light can be produced. Other variations are also possible, depending upon the filter design and the desired optical response.

Optical sensor devices produced in accordance with embodiments of the present invention should provide a better performance to cost ratio compared to sensors including either a color organic filter or an inorganic optical dielectric filter alone. Embodiments of the present invention also allow an IR-based proximity and/or motion sensor to be fabricated on a same wafer alongside an ambient light sensor (ALS) and/or one or more sensors configured to detect light of specific colors, such as, but not limited to, red, green and blue (RGB). In other words, a monolithic semiconductor device can include a plurality of light sensors each of which has a different response intended for a different purpose. Alternatively, or additionally, responses of two or more light sensors within the same monolithic device can be combined to provide a desired response, such as a photopic response.

In certain embodiments, other circuitry, such as, amplifier circuitry that is used to amplify photocurrents produced by PD regions and/or driver circuitry that can be used to selectively drive the a light source (for use in proximity and/or motion sensor applications) can be fabricated into the same semiconductor substrate that includes the PD regions that are selectively covered by one or more filters, as described above.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A method for manufacturing a monolithic optical sensor device, comprising:
(a) depositing and thereby forming one or more inter metal dielectric (IMD) layer(s) over a plurality of photodetector (PD) regions in a semiconductor wafer substrate;
(b) depositing and thereby forming a wafer-level inorganic dielectric optical filter over at least a portion of an uppermost said IMD layer that is over at least a subset of the plurality of PD regions; and
(c) depositing and thereby forming one or more wafer-level organic color filter(s) on one or more selected portion(s) of the wafer-level inorganic dielectric optical filter that is/are over selected ones of the PD regions.

2. The method of claim 1, wherein:
step (a) includes depositing and thereby forming one or more inter metal dielectric (IMD) layer(s) over a first PD region, a second PD region and a third PD region in the semiconductor wafer substrate;
step (b) includes depositing and thereby forming the wafer-level inorganic dielectric optical filter over at least a portion of the uppermost said IMD layer that is over the first, second and third PD regions; and
step (c) includes depositing and thereby forming
a first wafer-level organic color filter over at least a portion of the wafer-level inorganic dielectric optical filter that is over the first PD region;
a second wafer-level organic color filter over at least a portion of the wafer-level inorganic dielectric optical filter that is over the second PD region; and
a third wafer-level organic color filter over at least a portion of the wafer-level inorganic dielectric optical filter that is over the third PD region;
wherein the first, second and third wafer-level organic color filters differ in color from one another.

3. The method of claim 2, wherein the wafer-level inorganic dielectric optical filter comprises an IR-cut filter configured to reject infrared (IR) light and pass visible light.

4. A method of claim 3, wherein:
the first wafer-level organic color filter is red;
the second wafer-level organic color filter is green; and
the third wafer-level organic color filter is blue.

5. The method of claim 3, wherein:
step (a) also includes depositing and thereby forming the one or more IMD layer(s) over a fourth (PD) region in the semiconductor wafer substrate; and
further comprising
(e) depositing and thereby forming a second wafer-level inorganic dielectric optical filter over at least a portion of the uppermost said IMD layer that is over the fourth PD region;
wherein the second wafer-level inorganic dielectric optical filter comprises an IR-pass filter configured to pass IR light and reject visible light.

6. The method of claim 3, wherein:
step (a) also comprises depositing and thereby forming the one or more IMD layer(s) over a fourth (PD) region in the semiconductor wafer substrate; and
further comprising depositing and thereby forming one or more wafer-level organic color filter(s) over at least a portion of the uppermost said IMD layer that is over the fourth PD region.

7. The method of claim 1, further comprising:
between steps (b) and (c), depositing and thereby forming one or more passivation layer(s) on the uppermost said IMD layer;
wherein at step (c) the one or more wafer-level organic color filter(s) are deposited and thereby formed on the uppermost said passivation layer.

8. A method for manufacturing a plurality of monolithic optical sensor devices, comprising:
(a) depositing and thereby forming a wafer-level inorganic dielectric optical filter over a plurality of PD regions formed in a semiconductor wafer substrate;
(b) depositing and thereby forming a first wafer-level organic color filter on portions of the wafer-level inorganic dielectric optical filter that are over a first subset of the plurality of PD regions;
(c) depositing and thereby forming a second wafer-level organic color filter on further portions of the wafer-level inorganic dielectric optical filter that are over a second subset of the plurality of PD regions; and
(d) dicing the semiconductor wafer substrate into a plurality of monolithic optical sensor devices, each of which includes
at least one of the PD regions covered by both the wafer-level inorganic dielectric optical filter and the first wafer-level organic color filter, and
at least one of the PD regions covered by both the wafer-level inorganic dielectric optical filter and the second wafer-level organic color filter.

9. The method of claim 8, wherein each of the monolithic optical sensor devices also includes at least one PD region not covered by the wafer-level inorganic dielectric optical filter formed at step (a).

10. The method of claim 8, further comprising, prior to step (a), depositing and thereby forming one or more inter metal dielectric (IMD) layer(s) over the plurality of PD regions in the semiconductor wafer substrate.

11. A monolithic optical sensor device, comprising:
a semiconductor wafer substrate including a plurality of photodetector (PD) regions;
one or more inter metal dielectric (IMD) layer(s) over the plurality of PD regions;
a wafer-level inorganic dielectric optical filter over at least a portion of an uppermost said IMD layer that is over at least a subset of the plurality of PD regions; and
one or more wafer-level organic color filter(s) on one or more selected portion(s) of the wafer-level inorganic dielectric optical filter that is/are over selected ones of the PD regions.

12. The monolithic optical sensor device of claim 11, wherein:
the semiconductor wafer substrate includes at least a first PD region, a second PD region and a third PD region;
the one or more IMD layer(s) is/are over at least the first, second and third PD regions;
the wafer-level inorganic dielectric optical filter is over at least a portion of an uppermost said IMD layer that is over the first, second and third PD regions;
a first wafer-level organic color filter is over at least a portion of the wafer-level inorganic dielectric optical filter that is over the first PD region;
a second wafer-level organic color filter is over at least a portion of the wafer-level inorganic dielectric optical filter that is over the second PD region; and
a third wafer-level organic color filter is over at least a portion of the wafer-level inorganic dielectric optical filter that is over the third PD region;
wherein the first, second and third wafer-level organic color filters differ in color from one another.

13. The monolithic optical sensor device of claim 12, wherein the wafer-level inorganic dielectric optical filter comprises an IR-cut filter configured to reject infrared (IR) light and pass visible light.

14. The monolithic optical sensor device of claim 13, wherein:
the first wafer-level organic color filter is red;
the second wafer-level organic color filter is green; and
the third wafer-level organic color filter is blue.

15. The monolithic optical sensor device of claim 13, wherein:
the semiconductor wafer substrate also includes a fourth PD region; and
further comprising a second wafer-level inorganic dielectric optical filter over at least a portion of the uppermost said IMD layer that is over the fourth PD region;
wherein the second wafer-level inorganic dielectric optical filter comprises an IR-pass filter configured to pass IR light and reject visible light.

16. The monolithic optical sensor device of claim 13, wherein:
the semiconductor wafer substrate also includes a fourth PD region; and
further comprising one or more wafer-level organic color filter(s) over at least a portion of the uppermost said IMD layer that is over the fourth PD region.

17. The monolithic optical sensor device of claim 11, further comprising:
one or more passivation layer(s) between the uppermost said IMD layer and the wafer-level inorganic dielectric optical filter.

18. A monolithic optical sensor device, comprising:
a semiconductor wafer substrate including a plurality of photodetector (PD) regions;
a wafer-level inorganic dielectric optical filter over at least a subset of the plurality of PD regions; and
one or more wafer-level organic color filter(s) on one or more selected portion(s) of the wafer-level inorganic dielectric optical filter that is/are over selected ones of the PD regions.

19. The monolithic optical sensor device of claim 18, wherein:
the semiconductor wafer substrate including at least a first PD region, a second PD region and a third PD region;
a first wafer-level organic color filter is over at least a portion of the wafer-level inorganic dielectric optical filter that is over the first PD region;
a second wafer-level organic color filter is over at least a portion of the wafer-level inorganic dielectric optical filter that is over the second PD region; and
a third wafer-level organic color filter is over at least a portion of the wafer-level inorganic dielectric optical filter that is over the third PD region;
wherein the first, second and third wafer-level organic color filters differ in color from one another.

20. The monolithic optical sensor device of claim 18, further comprising:
the one or more IMD layer(s) and one or more passivation layer(s) between the semiconductor wafer substrate and the wafer-level inorganic dielectric optical filter.
